(19) United States
(12) Patent Application Publication
(10) Pub. No.: US 2026/0096147 A1
(43) Pub. Date: Apr. 2, 2026

(54) DISCONTINUOUS HIGH DIELECTRIC CONSTANT (HK) LAYER

(71) Applicant: International Business Machines Corporation, Armonk, NY (US)

(72) Inventors: Debarghya Sarkar, Latham, NY (US); Takashi Ando, Eastchester, NY (US); Abir Shadman, Albany, NY (US); Shay Reboh, Guilderland, NY (US); Junli Wang, ALBANY, NY (US); Paul Charles Jamison, Averill Park, NY (US)

(21) Appl. No.: 18/901,066

(22) Filed: Sep. 30, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/115; H10D 62/121; H10D 62/151; H10D 84/0149; H10D 84/038; H10D 84/83

(57) ABSTRACT

A stacked field effect transistor structure includes a lower field effect transistor with a lower first drain-source region, a lower second drain-source region, and at least one lower nanosheet channel region interconnecting the lower drain-source regions. An upper field effect transistor has an upper first drain-source region, an upper second drain-source region, and at least one upper nanosheet channel region interconnecting the upper drain-source regions. A high-K metal gate structure surrounds at least a portion of the lower and upper nanosheet channel regions. A middle dielectric isolation region separates the upper and lower field effect transistors. Gate spacers are on sides of the gate structure, which includes gate metal, and high-K liner material on the lower and upper nanosheet channel regions, and in a first wall region extending up the gate spacers next to the lower field effect transistor no further than the middle dielectric isolation region.

### BACKGROUND

The present invention relates generally to the electrical, electronic, and computer arts, and, more particularly, to semiconductor devices including stacked field effect transistors (FETs).

In a stacked-FET semiconductor device, matched work function (WF) gate stacks are helpful to achieve appropriate threshold voltages for the PFET (p-type FET) and the NFET (n-type FET) individually. However, there is a known issue in the stacked-FET architecture; namely, the PFET and NFET are, from an area standpoint, essentially at the same physical location of the chip and are stacked vertically. Thus, masking strategies that may be applicable for structures with the PFET and the NFET at different locations of the chip, from an area standpoint, cannot be used for stacked FET devices.

### BRIEF SUMMARY

Principles of the invention provide techniques for a stacked FET and with discontinuous HK layer on the gate spacer inner sidewall. In one aspect, an exemplary stacked field effect transistor structure includes a lower field effect transistor including a lower first drain-source region, a lower second drain-source region, and at least one lower nanosheet channel region interconnecting the lower first and lower second drain-source regions; an upper field effect transistor including an upper first drain-source region, an upper second drain-source region, and at least one upper nanosheet channel region interconnecting the upper first and upper second drain-source regions; and a high-K metal gate structure surrounding at least a portion of the at least one lower nanosheet channel regions and at least a portion of the at least one upper nanosheet channel region. Also included are a middle dielectric isolation region separating the upper and lower field effect transistors; and gate spacers on sides of the high-K metal gate structure. The high-K metal gate structure includes: gate metal; and high-K liner material on the at least one lower nanosheet channel region, the at least one upper nanosheet channel region, and in a first wall region extending up the gate spacers next to the lower field effect transistor no further than the middle dielectric isolation region.

In another aspect, an exemplary stacked field effect transistor array includes a plurality of stacked field effect transistor structures as just described, and at least one wiring structure with a plurality of horizontal wires and a plurality of vertical contacts selectively connected to at least a subset of the gate structures, and at least a subset of: the lower first drain-source regions, the lower second drain-source regions, the upper first drain-source regions and the upper second drain-source regions.

In still another aspect, an exemplary method of forming a stacked field effect transistor structure includes providing an initial structure. The initial structure includes a lower field effect transistor precursor structure including a lower first drain-source region, a lower second drain-source region, and at least one lower nanosheet channel region interconnecting the lower first and lower second drain-source regions; an upper field effect transistor precursor structure including an upper first drain-source region, an upper second drain-source region, and at least one upper nanosheet channel region interconnecting the upper first and upper second drain-source regions; and a middle dielectric isolation region separating the upper and lower field effect transistor precursor structures. The initial structure further includes a substrate structure under the lower field effect transistor precursor structure, the substrate structure including a silicon portion and shallow trench isolation portions separated from the silicon portion by nitride layers; and gate spacers extending upward from the shallow trench isolation portions. Further steps include depositing first high-K liner material and a cap layer on the at least one lower nanosheet channel region, the at least one upper nanosheet channel region, the middle dielectric isolation region, a portion of the substrate structure inward of the gate spacers, and the gate spacers; removing the first high-K liner material and the cap layer from the at least one upper nanosheet channel region, a top surface and sides portions of the middle dielectric isolation region, and portions of the gate spacers extending above the middle dielectric isolation region; depositing additional high-K liner material on the at least one upper nanosheet channel region; removing the cap layer from the bottom surface of the middle dielectric isolation region, portions of the gate spacers extending below the middle dielectric isolation region, the portion of the substrate structure inward of the gate spacers, and the at least one lower nanosheet channel region; and depositing n-type work function metal on the at least one lower nanosheet channel region, the at least one upper nanosheet channel region, the middle dielectric isolation region, the portion of the substrate structure inward of the gate spacers, and the gate spacers. Still further steps include filling in gate metal around the at least one lower nanosheet channel region, the at least one upper nanosheet channel region, and the middle dielectric isolation region; removing the silicon portion of the substrate structure to create a cavity and expose an adjacent portion of the first high-K liner material and carrying out O₂ annealing of the exposed adjacent portion; and depositing backside inter-layer dielectric in the cavity.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
techniques to simultaneously obtain PFET and NFET matched work function in the same vertical stack by preferentially affecting only the PFET and not the NFET during O₂ annealing;
techniques that can be implemented using known processes, such as processes that have already been on previous or current technology nodes;

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a generalized top view representing both intermediate structures and a final stacked field effect transistor structure, in accordance with aspects of the invention;

FIG. 2 is a starting structure viewed along line II-II of FIG. 1, in accordance with aspects of the invention;

FIGS. 3-12 depict process steps operating on the starting structure of FIG. 2, in accordance with aspects of the invention;

FIGS. 13 and 14 depict alternative process, in accordance with aspects of the invention; and FIG. 15 depicts a stacked field effect transistor array, in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As noted, there is a known issue in the stacked-FET architecture; namely, the PFET and NFET are, from an area standpoint, essentially at the same physical location of the chip and are stacked vertically. Thus, masking strategies that may be applicable for structures with the PFET and the NFET at different locations of the chip, from an area standpoint, cannot be used for stacked FET devices. One or more embodiments advantageously address this issue in the prior art. One or more embodiments advantageously use a discontinuity in the HK layer on the inner wall of the gate spacer, so that the NFET does not have an oxygen diffusion pathway. In this manner, only the HK in the PFET channel receives oxygen supply during O₂ annealing. In one or more embodiments, using a structure that allows for oxygen supply through backside processing, a matched WF for both the NFET and the PFET of a stacked FET architecture can be obtained.

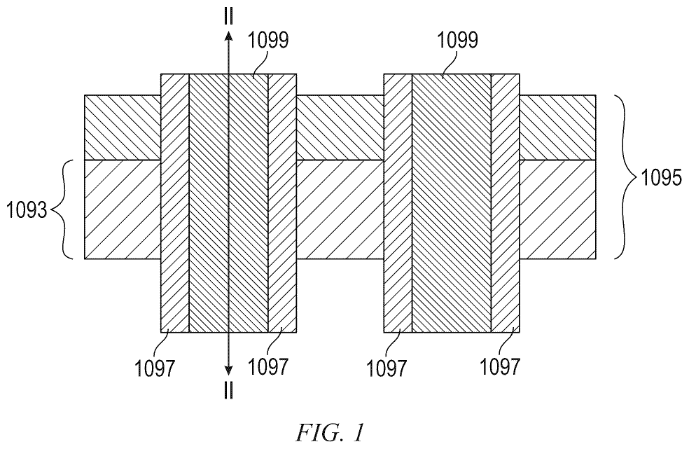

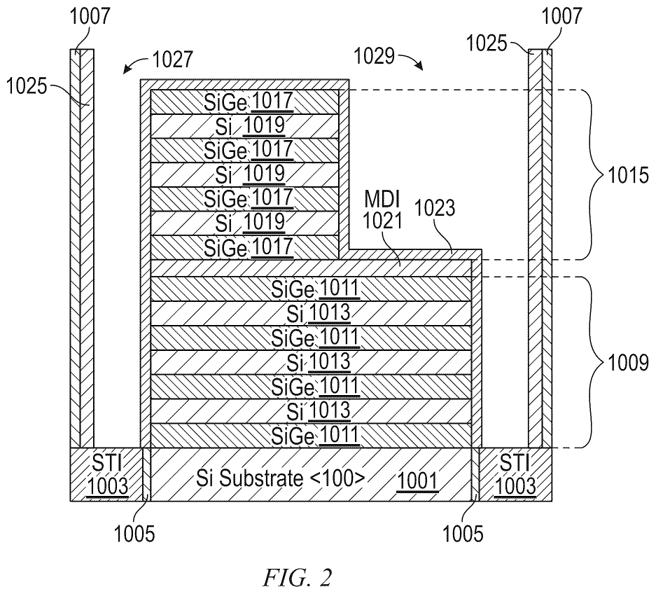

Refer now to the top view of FIG. 1 and the starting structure of FIG. 2, which depicts a replacement metal gate (RMG) module after polysilicon pull (i.e., dummy gate removal). FIG. 2 is taken along line II-II in FIG. 1, across the nanosheet stacks (channels) of the PFET and NFET, it being understood that FIG. 1 is a generalized top view showing a finished structure. In FIG. 1, note the replacement metal gates 1099, gate spacers 1097, PFET source-drain epitaxy 1095, and NFET source-drain epitaxy 1093 (which obscures part of 1095).

In FIG. 2, note the silicon substrate 1001, which can have a <100> crystal orientation, for example; the shallow trench isolation (STI) regions 1003; and the nitride layers 1005, 1007. Further note the PFET stack 1009 with alternating layers of PFET SiGe 1011 and PFET silicon (lower nanosheet channel regions 1013); and also the NFET stack 1015 with alternating layers of NFET SiGe 1017 and NFET silicon (top nanosheets 1019). Middle dielectric isolation (MDI) 1021 (e.g., SiBCN) covers an upper surface of the PFET stack and separates the PFET and NFET stacks. A first oxide 1023 covers sides and outer surfaces of the PFET and NFET stacks and sides of the MDI. Another SIBCN layer 1025 is provided on sides of nitride layer 1007 facing the PFET and NFET stacks.

As will be appreciated by the skilled artisan, the void areas 1027, 1029 represent where the polysilicon dummy gate material has been removed. Given the teachings herein, the skilled artisan can create the starting structure of FIG. 2 using known techniques from the field of stacked nanosheet FET formation and the high-K metal replacement gate (HKMG) process.

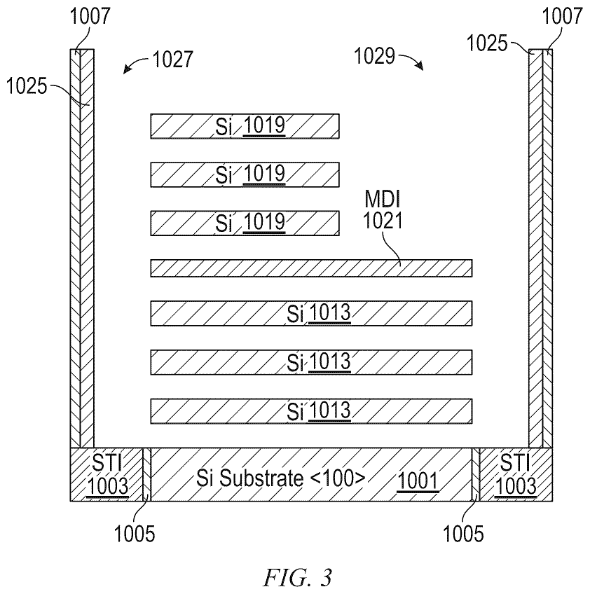

FIG. 3 shows the structure of FIG. 2 after channel release; i.e., etching the SiGe away selectively to the Si and removing the first oxide 1023. The Si and MDI are not “floating” but are anchored inward and outward of the plane of the figure in a known manner. Known selective etching techniques and the like can be employed.

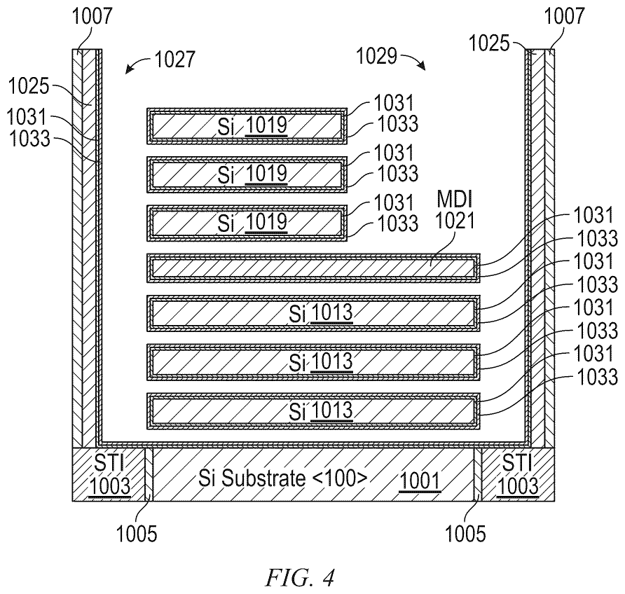

FIG. 4 shows the structure of FIG. 3 after deposition of high-K gate material 1031 and cap 1033 (e.g., TiN and amorphous silicon (a-Si)) on the elements 1025, 1003, 1001, 1013, 1021, and 1019 as shown, using known deposition techniques.

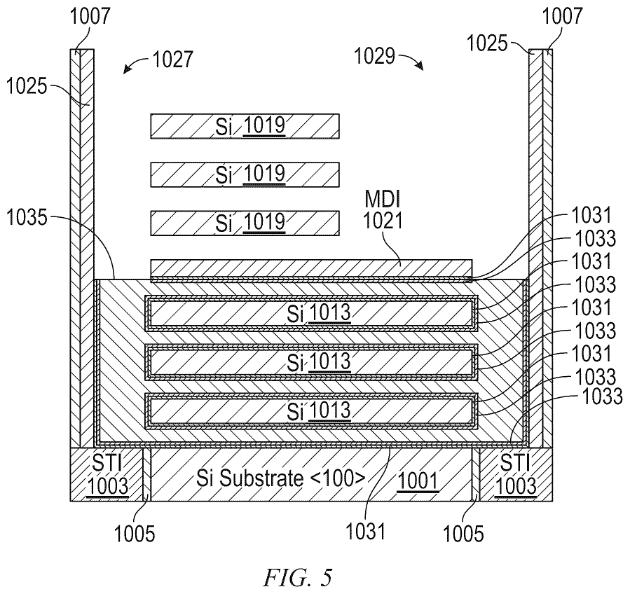

FIG. 5 shows the structure of FIG. 4 after removal of the high-K gate material 1031 and cap 1033 from the top device. Note the organic dielectric layer (ODL) 1035. For example, deposit and then partially recess the ODL 1035 so it protects the high-K gate material 1031 and cap 1033 for the bottom device and then etch away the high-K gate material 1031 and cap 1033 from the top device, using known deposition, recessing, and etching techniques.

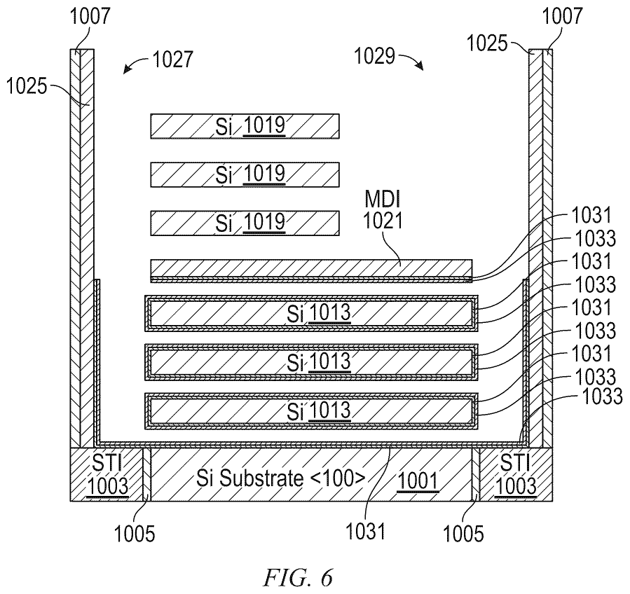

FIG. 6 shows the structure of FIG. 5 after removal of the ODL 1035, using known etching techniques, and carrying out a reliability anneal. A typical but non-limiting example can include laser anneal at 1250° C. for a time period on the order of msec.

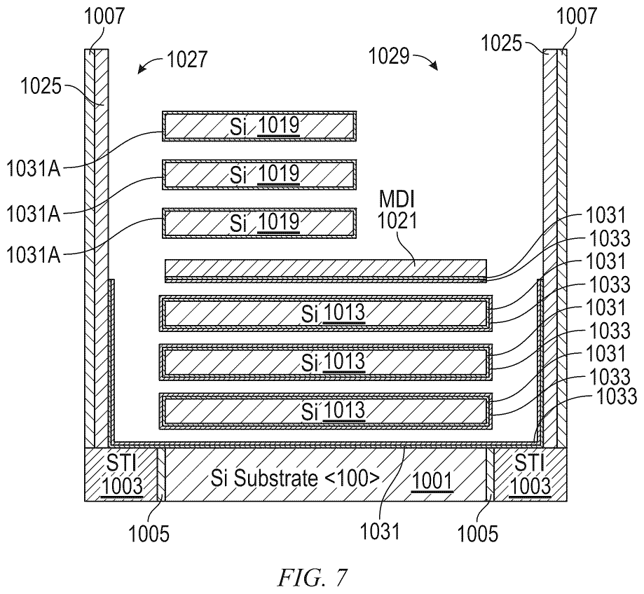

FIG. 7 shows the structure of FIG. 6 after selectively depositing high-K gate material (i.e., high-K dielectric part of the HKMG) 1031A only on the top nanosheets 1019 (i.e., selectively on the Si channels). Elements 1031 and 1031A can be the same material in one or more embodiments. HfO₂ can be used for both NFET and PFET in a non-limiting example. The exemplary process flow assumes the same high-K material to be deposited on both NFET and PFET. However, in general, element 1031A can be the same material as element 1031 or it can be different. To facilitate this deposition process for the top nanosheets 1019, for example, apply H₂ pulses to avoid (preferably, completely avoid) deposition on the top side wall (exposed SIBCN layer 1025) and a-Si of the cap 1033. In one or more embodiments, the surface of the top nanosheets 1019 (i.e., channel Si surface) has ChemOx which has a significant amount of hydroxyl (OH) radicals. “ChemOx” refers to chemical oxide. In one or more embodiments, before ALD deposition, a wet processing is performed (such as SC1), that makes the surface hydrophilic (introducing OH radicals). This hydrophilic surface aids in the proper deposition of high K material by the ALD process. Regarding the “significant” amount of hydroxyl (OH) radicals, ideally, most atomic sites on the surface are terminated with OH in order to deposit film with water-based ALD.

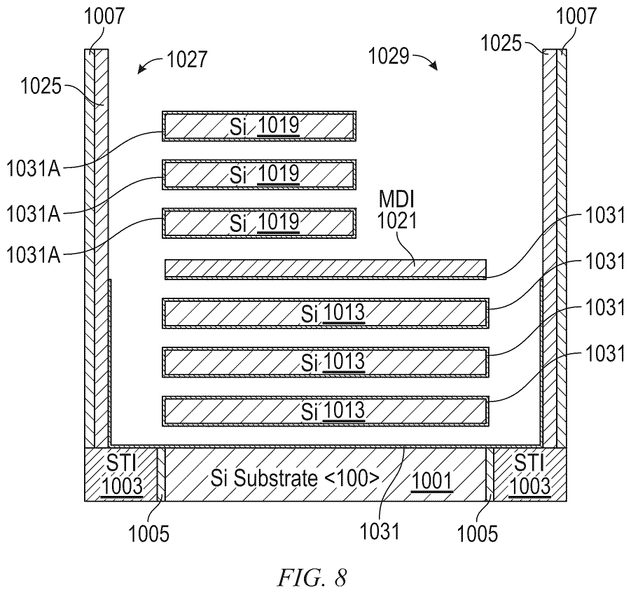

FIG. 8 shows the structure of FIG. 7 after removal of the cap 1033 using known etching techniques.

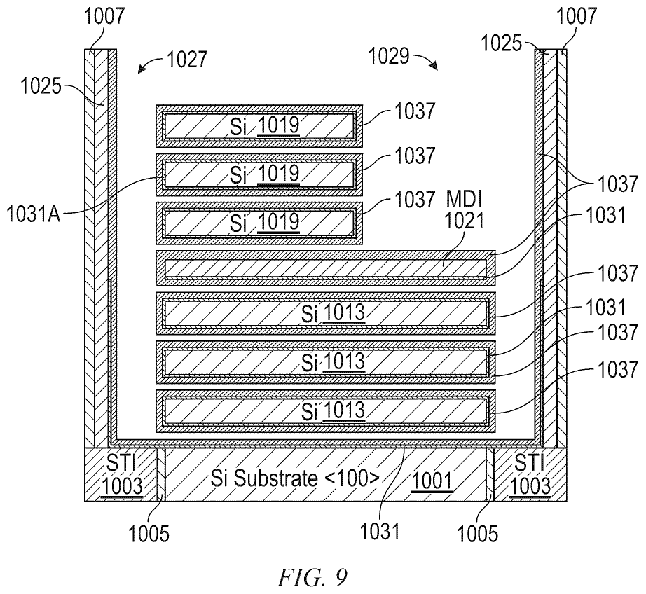

FIG. 9 shows the structure of FIG. 8 after deposition of n-type WFM (n-WFM) 1037 (e.g. TiAlC) using known deposition techniques. To avoid clutter, only some of the high-K gate material 1031 and high-K gate material 1031A is labeled in FIG. 8.

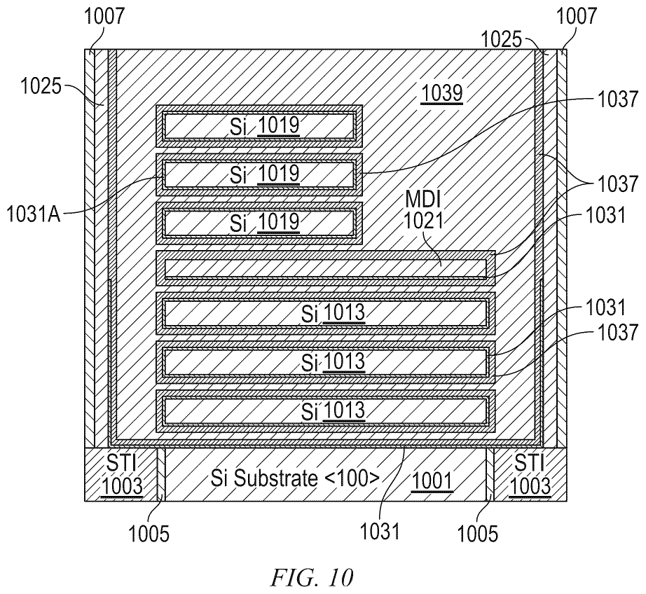

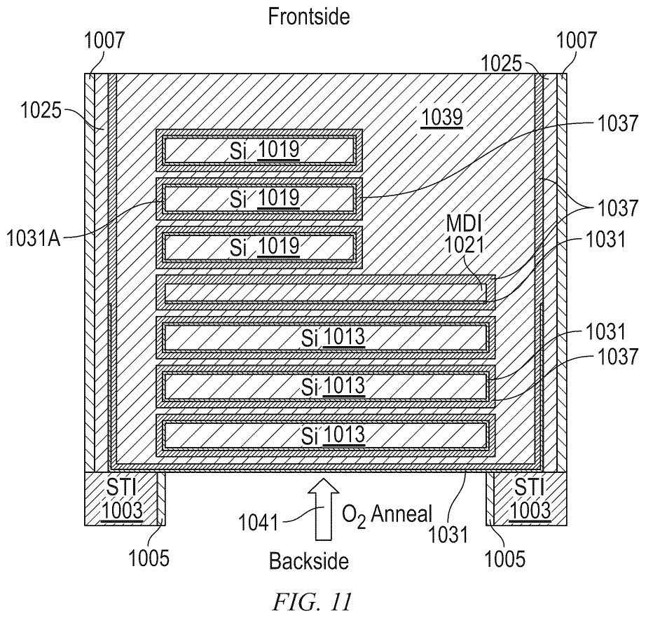

FIG. 10 shows the structure of FIG. 9 after deposition of gate metal 1039 (e.g., tungsten (W)) fill in void areas 1027, 1029 using known deposition techniques. To avoid clutter, only some of the high-K gate material 1031, high-K gate material 1031A, and n-type WFM 1037 is labeled in FIG. 9.

Note that after the structure of FIG. 10 is formed, conventional back end of line (BEOL) processing can be carried out to form front side interconnects and a carrier wafer can be bonded on top; the carrier wafer is then flipped and processing continues as described just below with regard to FIG. 11.

FIG. 11 shows the structure of FIG. 10 after frontside interconnect formation (not shown; done in a conventional manner as would be apparent to the skilled artisan given the teachings herein), carrier wafer bonding (not shown; done in a conventional manner as would be apparent to the skilled artisan given the teachings herein), backside Si removal (i.e., removal of Si 1001), and backside O₂ anneal as shown by block arrow 1041.

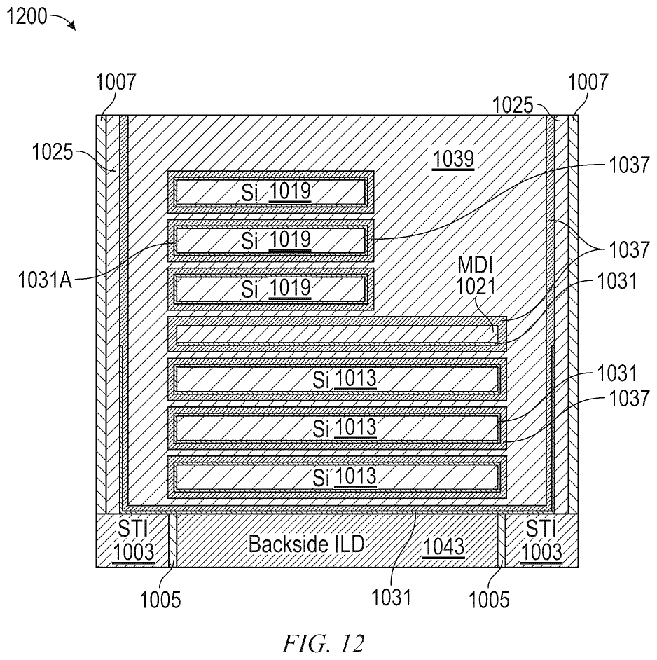

FIG. 12 shows a structure 1200 which results from the structure of FIG. 11 after backside dielectric fill (i.e., filling the cavity resulting from removal of Si 1001 with backside ILD 1043 (e.g., a second oxide).

It will accordingly be appreciated that in one aspect, an exemplary method to form a semiconductor device includes blanket HK+TiN/a-Si cap deposition (FIG. 4); selective removal of HK+TiN/a-Si cap from top device only (FIG. 5); selective area deposition of HK on the top device nanosheets only (not on the spacer sidewall or a-Si surface) (FIG. 7); TiN/a-Si removal selective to the HK (FIG. 8); blanket n-WFM (e.g., TiAlC) deposition (FIG. 9); gate metal (e.g., W) fill (FIG. 10); backside O₂ anneal (FIG. 11); and backside PC region dielectric fill (FIG. 12).

Stated in an alternative manner, in one or more embodiments, a structure is provided wherein FETs of opposite polarity are stacked on top of each other. Up until the stage of source-drain epitaxial growth (i.e., prior to FIG. 2), fabrication of the structure can be carried out according to the state of the art. Note dummy gate poly-Si removal (prior to starting structure of FIG. 2) and nanosheet release by selective removal of sacrificial layers between the channels (FIG. 3). HK+TiN/a-Si cap deposition is shown in FIG. 4. FIG. 5 shows ODL deposition, partial recess, and removal of the HK+TiN/a-Si cap from the top device. FIG. 6 shows ODL removal and FIG. 7 shows selective area deposition of HK only on the Si (top nanosheets 1019). FIG. 8 shows removal of the TiN/a-Si cap, while FIG. 9 shows deposition of n-WFM (e.g., TiAlC). FIG. 10 shows deposition of W fill. FIG. 11 relates to frontside interconnect formation (not explicitly shown), carrier wafer bonding (not explicitly shown), backside Si removal (depicted), and backside O₂ anneal (depicted). FIG. 12 shows the bottom of the gate back-filled with dielectric (e.g., backside ILD 1043).

Thus, one or more embodiments advantageously provide discontinuous high-K (HK) on the spacer sidewall (note in FIG. 12 the high-K gate material 1031 partially up the sidewall of SIBCN layer 1025). Optionally, one or more embodiments employ the same WFM 1037 for both transistors, where the presence of high-K material is used to tune the threshold voltage for the top transistor. Furthermore in this regard, in one or more embodiments, continuous presence of high-K material on the gate spacer sidewall beside the PFET and on the bottom of the gate, which is then exposed to oxygen supply, is used to tune the threshold voltage for the PFET transistor residing at the lower side of the gate. In one or more embodiments, the PFET region gate spacer sidewall material promotes HK nucleation and growth, while the NFET region gate spacer sidewall material hinders HK nucleation and growth. One example is having SiN with high H content in the NFET region, and SiN with low H content in the PFET region. This hinders OH termination in the spacer material beside the NFET, thereby hindering HK nucleation and growth.

Indeed, one or more embodiments provide a stacked transistor structure (in a non-limiting example, with the PFET on the bottom and the NFET on the top). Further, referring, for example, to FIG. 12, one or more embodiments provide a discontinuous High-K liner (high-K gate material 1031, 1031A) on nanosheets 1013, 1019 of both the top and bottom transistors, and associated with the bottom transistor adjacent SIBCN layer 1025. In one or more embodiments, the top surface of the high-K liner is at or below the level of middle dielectric isolation (MDI) 1021 (more generally, below the bottom nanosheet 1019 of the top device—no higher than the bottom of the lowest Si 1019 in the top device).

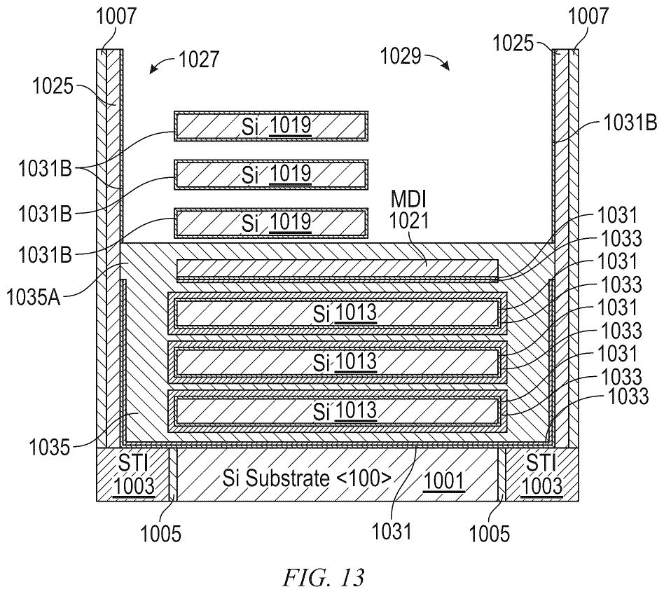

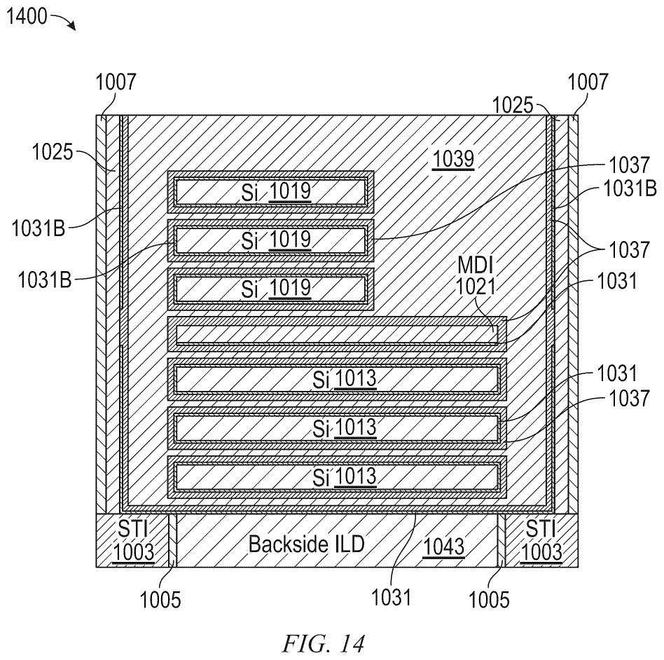

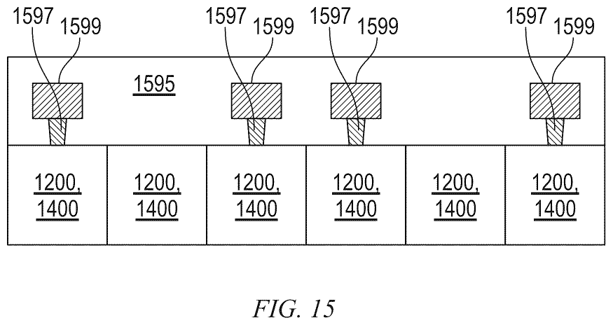

In another aspect, referring to FIGS. 13 and 14, additional High-K liner 1031B is associated with the top device and is separated from High-K liner (high-K gate material 1031) adjacent SIBCN layer 1025 by a gap. To achieve this configuration, for example, start with the structure of FIG. 5. Referring to FIG. 13, deposit additional ODL 1035A up to a height no higher than the bottom of the lowest Si 1019 in the top device. Then deposit additional High-K liner 1031B to cover the top nanosheets and the sidewall above the surface of additional ODL 1035A, and carry out a directional etch, repeating the pertinent steps from FIGS. 6-12, as would be apparent to the skilled artisan, obtaining the final structure 1400 in FIG. 14.

In some instances, the presence of high-K is used to tune the threshold voltage for the top transistor (e.g. PFET formed from PFET stack 1009). Optionally, the same work function metal is used for both the NFET (e.g., formed from NFET stack (including top nanosheets 1019)) and the PFET. In some instances, the PFET region gate spacer sidewall material promotes HK nucleation and growth, while the NFET region gate spacer sidewall material hinders HK nucleation and growth.

Stated in an alternative manner, one or more embodiments provide a semiconductor structure including complementary nanosheet FETs in a vertically-stacked form, with discontinuous HK on the inner wall of the gate spacer. In one or more embodiments, HK is present on the inner wall of the gate spacer surrounding the PFET only.

In one or more embodiments, HK is present on the inner wall of the gate spacer surrounding both the PFET and the NFET, but has a discontinuity in between, as seen in FIG. 14. In some instances, the PFET forms the bottom device. In some cases, the NFET and PFET have a common work function metal (e.g., TiAlC). In some instances, the backside bottom of the gate region has dielectric fill (backside ILD). In one or more embodiments, the PFET region gate spacer sidewall promotes HK nucleation and growth, while the NFET region gate spacer sidewall hinders HK nucleation and growth.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary stacked field effect transistor structure includes a lower field effect transistor including a lower first drain-source region, a lower second drain-source region, and at least one lower nanosheet channel region 1013 interconnecting the lower first and lower second drain-source regions (drain-source regions can be seen at 1095 in FIG. 1). The structure further includes an upper field effect transistor including an upper first drain-source region, an upper second drain-source region, and at least one upper nanosheet channel region (e.g., one of the top nanosheets 1019) interconnecting the upper first and upper second drain-source regions (drain-source regions can be seen at 1093 in FIG. 1). A high-K metal gate structure including elements 1031, 1031A, 1039 surrounds at least a portion of the at least one lower nanosheet channel region and at least a portion of the at least one upper nanosheet channel region. A middle dielectric isolation (MDI) 1021 region separates the upper and lower field effect transistors. Gate spacers 1007, 1025 are on sides of the high-K metal gate structure. The high-K metal gate structure includes: gate metal 1039; and high-K liner material on the at least one lower nanosheet channel region, the at least one upper nanosheet channel region (1031 and 1031A respectively), and in a first wall region extending up the gate spacers next to the lower field effect transistor no further than the middle dielectric isolation region (“side” element 1031 in FIG. 12).

In some instances, as seen in FIG. 12, there is no high-K liner material extending up the gate spacers beyond the first wall region.

On the other hand, as seen in FIG. 14, some cases further include additional high-K liner 1031B material extending up the gate spacers in a second wall region beyond the first wall region and separated therefrom by a gap.

In either case, the lower field effect transistor and the upper field effect transistor can be complementary; for example, the lower field effect transistor can be a p-type field effect transistor and the upper field effect transistor can be an n-type field effect transistor.

In either case, the stacked field effect transistor structure can further include a common work function metal (e.g., n-type WFM 1037 such as TiAlC) over the high-K liner material on the at least one lower nanosheet channel region, the high-K liner material on the at least one upper nanosheet channel region, the middle dielectric isolation region, and extending up the gate spacers.

In either case, the stacked field effect transistor structure can further include a backside inter-layer dielectric region (backside ILD 1043) under the lower field effect transistor; shallow trench isolation (STI) regions 1003 on left and right sides of the backside inter-layer dielectric region; and nitride layers 1005 separating the shallow trench isolation regions from the backside inter-layer dielectric region; where the high-K liner material and the common work function metal extend between the lower field effect transistor and the backside inter-layer dielectric region.

In either case, the stacked field effect transistor structure can further include at least a second lower nanosheet channel region 1013 interconnecting the lower first and lower second drain-source regions; and at least a second upper nanosheet channel region 1019 interconnecting the upper first and upper second drain-source regions; wherein the lower nanosheet channel regions are wider than the upper nanosheet channel regions.

In another aspect, referring to FIG. 15, a stacked field effect transistor array includes a plurality of stacked field effect transistor structures 1200 and/or 1400 as just described, and at least one wiring structure with a plurality of horizontal wires 1599 and a plurality of vertical contacts 1597 selectively connected to at least a subset of the gate structures and at least a subset of: the lower first drain-source regions, the lower second drain-source regions, the upper first drain-source regions and the upper second drain-source regions. Any desired elements can be in the array inverters, ring oscillators, statis random access memory (SRAM) and the like-anything with FETs as a fundamental unit. Known materials can be used to form standard interconnects to gate, drain, and source. There can be multiple wiring layers in the wiring structure and the wires and contacts can be in a dielectric 1595.

In still another aspect, a method of forming a stacked field effect transistor structure includes providing an initial structure (see, e.g., FIG. 3) including: a lower field effect transistor precursor structure including a lower first drain-source region, a lower second drain-source region, and at least one lower nanosheet channel region 1013 interconnecting the lower first and lower second drain-source regions; and an upper field effect transistor precursor structure including an upper first drain-source region, an upper second drain-source region, and at least one upper nanosheet channel region 1019 interconnecting the upper first and upper second drain-source regions. A middle dielectric isolation region (MDI) 1021 separates the upper and lower field effect transistor precursor structures. A substrate structure, under the lower field effect transistor precursor structure, includes a silicon portion and shallow trench isolation portions separated from the silicon portion by nitride layers. Gate spacers 1007, 1025 extend upward from the shallow trench isolation portions.

Further steps include depositing first high-K liner material and a cap layer on the at least one lower nanosheet channel region, the at least one upper nanosheet channel region, the middle dielectric isolation region, a portion of the substrate structure inward of the gate spacers, and the gate spacers, as per FIG. 4; removing the first high-K liner material and the cap layer from the at least one upper nanosheet channel region, a top surface and sides portions of the middle dielectric isolation region, and portions of the gate spacers extending above the middle dielectric isolation region, as per FIG. 5; and depositing additional high-K liner material on the at least one upper nanosheet channel region, as per, e.g., FIG. 7. Note, “first” and “additional” high-K liner material can generally be the same or different materials and the terms “first” and “additional” are terms of convenience to refer to the fabrication steps.

Still further steps include removing the cap layer from the bottom surface of the middle dielectric isolation region, portions of the gate spacers extending below the middle dielectric isolation region, the portion of the substrate structure inward of the gate spacers, and the at least one lower nanosheet channel region, as per FIG. 8; depositing n-type work function metal on the at least one lower nanosheet channel region, the at least one upper nanosheet channel region, the middle dielectric isolation region, the portion of the substrate structure inward of the gate spacers, and the gate spacers, as per FIG. 9; filling in gate metal around the at least one lower nanosheet channel regions, the at least one upper nanosheet channel region, and the middle dielectric isolation region, as per FIG. 10; removing the silicon portion of the substrate structure to create a cavity and expose an adjacent portion of the first high-K liner material and carrying out O annealing of the exposed adjacent portion, as per FIG. 11; and depositing backside inter-layer dielectric in the cavity, as per FIG. 12.

In some instances, referring, e.g., to FIGS. 6-12, depositing the additional high-K liner material on the at least one upper nanosheet channel region includes selectively depositing the additional high-K liner material only on the at least one upper nanosheet channel region, as in FIG. 7 (for example, use hydrogen pulses to prevent growth on some surface compared to others).

On the other hand, referring to FIGS. 13 and 14, some cases include depositing the additional high-K liner material on portions of the gate spacers extending above the middle dielectric isolation region, with a gap from the first high-K liner material.

It is worth noting that in some instances, the NFET and PFET can be matched in the sense that the NFET has work function metal tuned to obtain a threshold voltage Vt, n ideal for the NFET and the PFET has a different WFM tuned to obtain a threshold voltage Vt, p ideal for the PFET. Different nanosheet widths for the top and bottom devices are optional, and can be used as appropriate based on integration considerations. Wider bottom epitaxy enables easier contacting, and the need to contact from the back side can be avoided. Different widths also facilitate having different parameters for the different transistors.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of exemplary stacked FET structure(s) disclosed herein.

An integrated circuit in accordance with aspects of the present inventions can be employed in essentially any application and/or electronic system where one or more aspects of the exemplary stacked FET structure(s) disclosed herein would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A stacked field effect transistor structure comprising:
a lower field effect transistor comprising a lower first drain-source region, a lower second drain-source region, and at least one lower nanosheet channel region interconnecting the lower first and lower second drain-source regions;
an upper field effect transistor comprising an upper first drain-source region, an upper second drain-source region, and at least one upper nanosheet channel region interconnecting the upper first and upper second drain-source regions;
a high-K metal gate structure surrounding at least a portion of the at least one lower nanosheet channel region and at least a portion of the at least one upper nanosheet channel region;
a middle dielectric isolation region separating the upper and lower field effect transistors; and
gate spacers on sides of the high-K metal gate structure;
wherein the high-K metal gate structure includes:
gate metal; and
high-K liner material on the at least one lower nanosheet channel region, the at least one upper nanosheet channel region, and in a first wall region extending up the gate spacers next to the lower field effect transistor no further than the middle dielectric isolation region.

2. The stacked field effect transistor structure of claim 1, wherein there is no high-K liner material extending up the gate spacers beyond the first wall region.

3. The stacked field effect transistor structure of claim 2, wherein the lower field effect transistor and the upper field effect transistor are complementary.

4. The stacked field effect transistor structure of claim 3, wherein the lower field effect transistor comprises a p-type field effect transistor and the upper field effect transistor comprises an n-type field effect transistor.

5. The stacked field effect transistor structure of claim 4, further comprising a common work function metal over the high-K liner material on the at least one lower nanosheet channel region, the high-K liner material on the at least one upper nanosheet channel region, the middle dielectric isolation region, and extending up the gate spacers.

6. The stacked field effect transistor structure of claim 5, wherein the common work function metal comprises TiAlC.

7. The stacked field effect transistor structure of claim 5, further comprising:
a backside inter-layer dielectric region under the lower field effect transistor;
shallow trench isolation regions on left and right sides of the backside inter-layer dielectric region; and
nitride layers separating the shallow trench isolation regions from the backside inter-layer dielectric region;
wherein the high-K liner material and the common work function metal extend between the lower field effect transistor and the backside inter-layer dielectric region.

8. The stacked field effect transistor structure of claim 7, further comprising:
at least a second lower nanosheet channel region interconnecting the lower first and lower second drain-source regions; and
at least a second upper nanosheet channel region interconnecting the upper first and upper second drain-source regions;
wherein the lower nanosheet channel regions are wider than the upper nanosheet channel regions.

9. The stacked field effect transistor structure of claim 1, further comprising additional high-K liner material extending up the gate spacers in a second wall region beyond the first wall region and separated therefrom by a gap.

10. The stacked field effect transistor structure of claim 9, wherein the lower field effect transistor and the upper field effect transistor are complementary.

11. The stacked field effect transistor structure of claim 10, wherein the lower field effect transistor comprises a p-type field effect transistor and the upper field effect transistor comprises an n-type field effect transistor.

12. The stacked field effect transistor structure of claim 11, further comprising a common work function metal over the high-K liner material on the at least one lower nanosheet channel region, the high-K liner material on the at least one upper nanosheet channel region, the middle dielectric isolation region, and extending up the gate spacers.

13. The stacked field effect transistor structure of claim 12, wherein the common work function metal comprises TiAlC.

14. The stacked field effect transistor structure of claim 12, further comprising:
a backside inter-layer dielectric region under the lower field effect transistor;
shallow trench isolation regions on left and right sides of the backside inter-layer dielectric region; and
nitride layers separating the shallow trench isolation regions from the backside inter-layer dielectric region;
wherein the high-K liner material and the common work function metal extend between the lower field effect transistor and the backside inter-layer dielectric region.

15. The stacked field effect transistor structure of claim 14, further comprising:
at least a second lower nanosheet channel region interconnecting the lower first and lower second drain-source regions; and
at least a second upper nanosheet channel region interconnecting the upper first and upper second drain-source regions;
wherein the lower nanosheet channel regions are wider than the upper nanosheet channel regions.

16. A stacked field effect transistor array comprising:
a plurality of stacked field effect transistor structures comprising:
a lower field effect transistor comprising a lower first drain-source region, a lower second drain-source region, and at least one lower nanosheet channel region interconnecting the lower first and lower second drain-source regions;
an upper field effect transistor comprising an upper first drain-source region, an upper second drain-source region, and at least one upper nanosheet channel region interconnecting the upper first and upper second drain-source regions;
a high-K metal gate structure surrounding at least a portion of the at least one lower nanosheet channel region and at least a portion of the at least one upper nanosheet channel region;
a middle dielectric isolation region separating the upper and lower field effect transistors; and
gate spacers on sides of the high-K metal gate structure;
wherein the high-K metal gate structure includes:
gate metal; and
high-K liner material on the at least one lower nanosheet channel region, the at least one upper nanosheet channel region, and in a first wall region extending up the gate spacers next to the lower field effect transistor no further than the middle dielectric isolation region; and
at least one wiring structure with a plurality of horizontal wires and a plurality of vertical contacts selectively connected to at least a subset of the gate structures and at least a subset of:
the lower first drain-source regions, the lower second drain-source regions, the upper first drain-source regions and the upper second drain-source regions.

17. The stacked field effect transistor array of claim 16, wherein at least a portion of the plurality of stacked field effect transistor structures further comprise additional high-K liner material extending up the gate spacers in a second wall region beyond the first wall region and separated therefrom by a gap.

18. A method of forming a stacked field effect transistor structure, the method comprising:
providing an initial structure comprising:
a lower field effect transistor precursor structure comprising a lower first drain-source region, a lower second drain-source region, and at least one lower nanosheet channel region interconnecting the lower first and lower second drain-source regions;
an upper field effect transistor precursor structure comprising an upper first drain-source region, an upper second drain-source region, and at least one upper nanosheet channel region interconnecting the upper first and upper second drain-source regions;
a middle dielectric isolation region separating the upper and lower field effect transistor precursor structures;
a substrate structure under the lower field effect transistor precursor structure, the substrate structure including a silicon portion and shallow trench isolation portions separated from the silicon portion by nitride layers; and
gate spacers extending upward from the shallow trench isolation portions;
depositing first high-K liner material and a cap layer on the at least one lower nanosheet channel region, the at least one upper nanosheet channel region, the middle dielectric isolation region, a portion of the substrate structure inward of the gate spacers, and the gate spacers;
removing the first high-K liner material and the cap layer from the at least one upper nanosheet channel region, a top surface and sides portions of the middle dielectric isolation region, and portions of the gate spacers extending above the middle dielectric isolation region;
depositing additional high-K liner material on the at least one upper nanosheet channel region;
removing the cap layer from the bottom surface of the middle dielectric isolation region, portions of the gate spacers extending below the middle dielectric isolation region, the portion of the substrate structure inward of the gate spacers, and the at least one lower nanosheet channel region;
depositing n-type work function metal on the at least one lower nanosheet channel region, the at least one upper nanosheet channel region, the middle dielectric isolation region, the portion of the substrate structure inward of the gate spacers, and the gate spacers;
filling in gate metal around the at least one lower nanosheet channel region, the at least one upper nanosheet channel region, and the middle dielectric isolation region;
removing the silicon portion of the substrate structure to create a cavity and expose an adjacent portion of the first high-K liner material and carrying out O₂ annealing of the exposed adjacent portion; and
depositing backside inter-layer dielectric in the cavity.

19. The method of claim 18, wherein depositing the additional high-K liner material on the at least one upper nanosheet channel region comprises selectively depositing the additional high-K liner material only on the at least one upper nanosheet channel region.

20. The method of claim 18, further comprising depositing the additional high-K liner material on portions of the gate spacers extending above the middle dielectric isolation region, with a gap from the first high-K liner material.
